(19) United States
(12) Patent Application Publication
(10) Pub. No.: US 2014/0349156 A1
(43) Pub. Date: Nov. 27, 2014

(54) Method and Apparatuses for Providing Information for Maintenance and Service Purposes for a Battery Unit

(71) Applicants: Robert Bosch GmbH, Stuttgart (DE); Samsung SDI Co., Ltd., Yongin-si (KR)

(72) Inventor: Christoph Brochhaus, Aachen (DE)

(73) Assignees: Robert Bosch GmbH, Stuttgart (DE); Samsung SDI Co., Ltd., Yongin-si (KR)

(21) Appl. No.: 14/282,721

(22) Filed: May 20, 2014

(30) Foreign Application Priority Data
May 22, 2013 (DE) 10 2013 209 427.2

(51) Int. Cl. G01R 31/36; H01M 10/48

(52) U.S. Cl. CPC G01R 31/3651; H01M 10/482
USPC 429/90; 702/63

(57) ABSTRACT

A method for providing information for maintenance and service purposes for a battery unit includes capturing and quantizing use data for a battery unit and forming a histogram that has frequency values for the occurrence of particular values of the individual quantized use data items or values derived therefrom. At least one additional information carrier is ascertained that is set up to reconstruct the histogram, and the histogram and the at least one additional information carrier are stored in a nonvolatile memory. Furthermore, a data structure, a computer program and a battery management system are specified that are set up to perform the method, and also a battery and a motor vehicle, the drive system of which is connected to such a battery.

This application claims priority under 35 U.S.C. §119 to patent application no. DE 10 2013 209 427.2, filed on May 22, 2013 in Germany, the disclosure of which is incorporated herein by reference in its entirety.

### BACKGROUND

The disclosure relates to a method for providing information for maintenance and service purposes for a battery unit, wherein use data for a battery unit are captured and quantized and wherein histograms are formed that have frequency values for the occurrence for particular values of the individual quantized use data items or values derived therefrom.

In addition, a data structure having such information is specified, and also a computer program and a battery management system that are set up particularly for performing the method. In addition, a battery and a motor vehicle having such a battery are specified.

Electronic controllers are used in increasing numbers in the automotive environment today. Examples of these are engine controllers or controllers for ABS or the airbag. For electrically driven vehicles, the focal point of research today is the development of powerful battery packs having associated battery management systems, i.e. controllers that are equipped with a piece of software for monitoring the battery functionality. Battery management systems ensure the safe and reliable operation, inter alia, of the battery cells and battery packs used. They monitor and control currents, voltages, temperatures, isolating resistors and further variables for individual cells and/or the entire battery pack. These variables can be used to provide management functions that increase the life, reliability and safety of the battery system.

DE 10 2010 031 337 A1 shows a method of ascertaining the probably life of battery cells. In order to ascertain the probable life of battery cells, physical variables and/or the number of performances of processes taking place in the battery cells are ascertained for a plurality of operating cycles and the frequency of occurrence of particular values of the physical variables and/or the frequency of the number of performances of at least one particular process are stored. This allows early identification of cell defects, inter alia, prevention thereof and the attainment of precise insights into the probable life of the battery cell.

### SUMMARY

A method according to the disclosure for providing information for maintenance and service purposes for a battery unit involves provision for at least one additional information carrier to be ascertained that is set up to reconstruct the histogram, and for the histogram and the at least one additional information carrier to be stored in a nonvolatile memory.

Advantageously, a history of the use of the battery is kept that can be read and used both for warranty claims and for the purpose of evaluating the use of the battery, for example for the purpose of ascertaining the probable life or the state of health (SOH) of the battery unit. This involves histograms being formed, the histograms having numbers of capture operations for the respective quantized use data item or values derived therefrom that can be associated with the individual quantized use data items. The histograms are particularly advantageously suitable for ascertaining the life and the state of health and ageing of the battery unit. By using a counter for the driving cycles, it is furthermore possible to draw conclusions as to the average use of the battery unit per driving cycle. Hence, there is a complete overview of the use of the battery during the life to date. For warranty claims too, it is possible for the histogram to be read from the nonvolatile memory of the controller and to be used for the purpose of evaluating the use of the battery.

The histogram is updated after every driving cycle. A histogram therefore comprises the frequency values for the occurrence of particular values of the individual quantized use data items for the last driving cycle and the previous driving cycles. By way of example, the events triggering a start and an end of the driving cycle may be charging pulses, a state change for the battery from “Operation” (Drive) to “Charge”, evaluation of a signal “charge active” or else evaluation of a state change at terminal 15, i.e. for the ignition positive. Similarly, the event triggering the start and the end of the driving cycle may be defined by detection of what is known as battery balancing. By way of example, the driving cycle can be defined by virtue of its also comprising or not also comprising a subsequent charging process.

During the driving cycle, the histogram is preferably updated in a volatile memory of a central controller. After the driving cycle, the histogram is written to a nonvolatile memory of the controller. A nonvolatile memory of this kind is what is known as an EEPROM (electrically erasable programmable read-only memory), for example, i.e. a nonvolatile, electronic memory chip whose stored information can be electrically erased.

A capture rate for the use data for the battery unit preferably has a defined value between 6/s and 6/h, preferably between 1/s and 1/min, particularly preferably 6/min or 1/min. After the defined intervals of time, the present temperature and the present voltage of the cells are recorded in the histogram, for example. For measured values such as temperature and SOC, it is possible for further preferred sampling rates to be between 1/min and 6/h, particularly to be approximately 1/min. For voltages, a filtered value is preferably stored, for example a mean value over a defined period, preferred periods likewise being approximately 1 min. The capture rate for the respective use data for the battery unit is preferably in a range that supports onboard diagnosis (OBD).

By way of example, the use data for the battery comprise the temperature, the state of charge, the output current or the provided voltage. Similarly, use data may comprise variables derived therefrom, for example variables that are summed or integrated with respect to time, variables that are multiplied by one another or aggregated otherwise, such as also what is known as the state of health (SOH) of the battery in suitable quantifiable units. Furthermore, differential values between minimum and maximum states, for example states of charge, relative battery powers or number of performances of charging and discharge cycles, may be included in the use data.

By way of example, derived values can denote relative frequencies, systematic shifts or weightings for the capture operations for the use data that are suitable for increasing the validity or the comparison power of the captured use data.

The quantization of the captured use data denotes that sampling points are defined that each represent boundaries for intervals, and the captured use data are associated with the intervals. In this case, the intervals may be defined to have a different magnitude or regularity. By way of example, a temperature range between −40° C. and +80° C. may be defined and divided into intervals of 10° C., 5° C., 2° C. or 1° C. For the magnitude and number of the intervals, firstly the memory taken up by the histogram in this case and secondly the validity of the captured use data quantized in this manner are taken into account.

According to one embodiment, the additional information carrier is a copy of the histogram. In this case, the histogram is thus stored in duplicate in the nonvolatile memory with what is known as a backup version. If it has been ascertained that the histogram is corrupt, it is possible to use the backup version to restore the histogram.

According to one embodiment, a checksum is formed for at least one portion of the histogram. Such checksums are suitable for determining whether a histogram is corrupt or whether it can be used for analyzing use information. Similarly, it is possible to form a checksum for the backup version or portions of the backup version of the histogram so as to render these likewise able to be checked for consistency.

By way of example, the checksum is formed by means of a cyclic redundancy check or application of a hash function. In the case of the cyclic redundancy check (CRC), a bit string of the histogram is divided by a stipulated generator polynomial, what is known as the CRC polynomial, modulo 2, with a remainder being left. This remainder is the CRC value that is appended to the data. In addition to this or as an alternative to this, a hash function, such as SHA-1, SHA-2 or SHA-3, may be provided, which is known to map the input quantity, in this case the relevant portion of the histogram, onto a small target quantity, the hash values. Hash functions are suitable for confirming the integrity of the data. That is to say that it is practically impossible to use intentional modification to produce a data stream that has the same hash value as a given message.

According to a further embodiment, the histogram is split into partitions. With particular preference, at least one checksum is formed for each partition, said checksum allowing identification of erroneous information on the partition. If an additional information carrier is a backup version, it is also possible to break down the copy into partitions for safety, and to form individual checksums using the partitions of the copy.

Provision may be made for an additional information carrier to be ascertained for each partition, which additional information carrier is set up to reconstruct the partition. However, information carriers that are known in connection with RAID (Redundant Array of Independent Disks) systems, for example, are preferred. A priority in this case is that if individual components of the system fail then the RAID as a whole keeps its integrity and, following replacement of the failed component or components, the original state can be restored. In this case, the histogram is first of all partitioned and each partition is stored together with a checksum. In order to identify single errors on individual partitions, provision is made for the additional information carrier to comprise parity data for the partitions. In this case, the reconstruction data in the form of the parity data take up the memory space from the largest of the partitions. The reconstruction data can likewise be safeguarded by checksum. If the checksum is used to identify that a partition is corrupt, it is possible to use the reconstruction data to restore the partition ascertained as being corrupt.

Therefore, the method is capable of identifying and rectifying single errors. In addition, a signal indicating that there is an error can be output, so that a repair can be made before further errors arise. According to a further embodiment, information carriers are ascertained by a combination of different methods, such as RAID4 and RAID5, and also allow reconstruction in the event of multiple errors, i.e. when multiple partitions are corrupt.

The presented method can be used particularly on lithium ion batteries and on nickel metal hydride batteries. Preferably, it is used on multiple and particularly on all cells of one or more batteries that are essentially operated simultaneously.

The disclosure furthermore proposes a data structure having at least one histogram that has frequency values for the occurrence of particular values of quantized use data or values derived therefrom, and having at least one additional information carrier that is set up to reconstruct the histogram. The data structure has preferably been created during the performance of one of the methods described. By way of example, the data structure is read by a computer device for maintenance and service purposes, for the purpose of updating information, for the purpose of identifying erroneous information, for the purpose for validating information or for the purpose of reconstructing the information.

The disclosure also proposes a computer program according to which one of the methods described herein is performed when the computer program is executed on a programmable computer device. By way of example, the computer program may be a module for implementing a device for providing or for reading information for maintenance and service purposes for a battery unit and/or may be a module for implementing a battery management system for a vehicle. The computer program can be stored on a machine-readable storage medium, for example on a permanent or rewritable storage medium or in association with a computer device, for example on a portable memory, such as a CD-ROM, DVD, a USB stick or a memory card. In addition or as an alternative to this, the computer program can be provided on a computer device, such as on a server or a cloud server, for download, for example via data network, such as the internet, or a communication link, such as a telephone line or a wireless connection.

Furthermore, the disclosure provides a battery management system (BMS), having a unit for capturing use data for a battery unit, a unit for quantizing the captured use data, a unit for creating or updating a histogram over a driving cycle, which histogram has frequency values for the occurrence of particular values for the individual quantized use data items or values derived therefrom, a unit for ascertaining an additional information carrier that is set up to reconstruct the histogram and a unit for storing the histogram and the at least one additional information carrier in a nonvolatile memory.

Furthermore, the disclosure provides a battery, particularly a lithium ion battery or a nickel metal hydride battery, that comprises a battery management system and can be connected to a drive system in a motor vehicle, wherein the battery management system is in a form as described previously and/or is set up to carry out the method according to the disclosure.

In the present description, the terms “battery” and “battery unit” are used for storage battery or storage battery unit in a manner customized to ordinary language use. The battery preferably comprises one or more battery units that are able to comprise a battery cell, a battery module, a line of modules or a battery pack. In this case, the battery cells are preferably physically combined and connected to one another in terms of circuitry, for example connected up in series or in parallel to form modules. A plurality of modules can form what are known as battery direct converters (BDC) and a plurality of battery direct converters can form a battery direct inverter (BDI).

Furthermore, the disclosure provides a motor vehicle having such a battery, wherein the battery is connected to a drive system in the motor vehicle. Preferably, the method is used for electrically driven vehicles in which a multiplicity of battery cells are interconnected in order to provide the necessary drive voltage.

The method according to the disclosure allows use data for the batteries to be analyzed even in the case of memory errors, i.e. even when said use data have been partially destroyed during their life. In this case, checksums are used to identify when a histogram is corrupt. If the check establishes that a histogram is corrupt, it is restored by means of the reconstruction files and can be used to analyze the battery again. In principle, it is possible to use all known methods for safeguarding and reconstructing data inventories, for example methods for restoring faulty hard disks, etc. Depending on the chosen method, it is possible to rectify single errors or multiple errors. The additional memory involvement is likewise dependent on the chosen method.

Furthermore, the controller is provided with the option of identifying memory faults, and this is able to react accordingly and to discontinue use of the faulty memory cells.

A further advantage is obtained through the scalability of the system. The number of captured measured variables, i.e. of dimensions of the histogram, can be extended as desired. It is thus also possible to use highly dimensional histograms that, for example, provide information about how long a battery has been used with a particular combination of a defined state of charge, a defined temperature and a defined flow of current. Furthermore, the method can be used on different independent histograms in parallel.

### BRIEF DESCRIPTION OF THE DRAWINGS

Exemplary embodiments of the disclosure are shown in the drawings and are explained in more detail in the description below.

In the drawings:

FIG. 1 shows an example of updating of a two-dimensional histogram,

FIG. 2 shows an example of duplicate storage of a histogram with an additional information carrier,

FIG. 3 shows an example of storage of a histogram with two partitions and an additional information carrier, and

FIG. 4 shows an example of a stored histogram with an additional information carrier.

### DETAILED DESCRIPTION

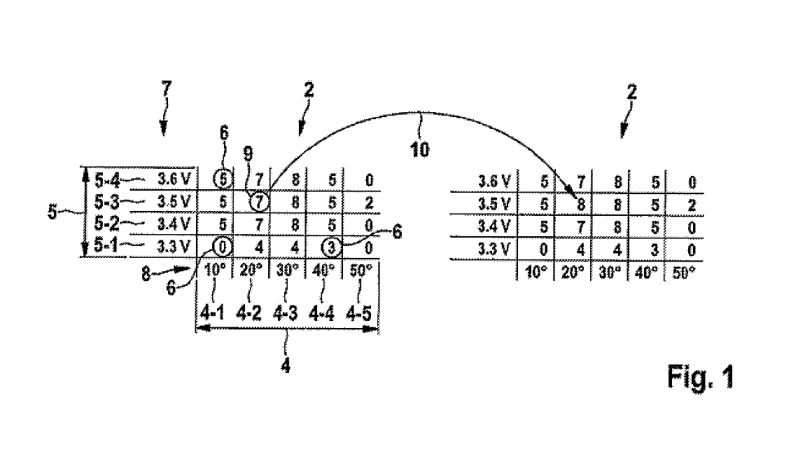

FIG. 1 shows a two-dimensional histogram 2 before and after an update step, which in this case is shown by way of example as an arrow 10. When the histogram 2 is created, the temperature and the voltage are ascertained at a defined capture rate and the relevant frequency value 6 is increased by 1. In the example, an update step 10 with an increase for the frequency value 6 for the measurement 9 “20°/3.5 Volts” is shown. From the histogram 2, it is evident after the update step 10, for example, that the battery has been operated at 20° C. and a voltage of 3.5 V for 8 measurements, or else that the battery has never been operated at 10° C. and 3.3 V.

In the example shown, a total interval 4 of temperatures of 10° C. to +50° C. is split into 5 single intervals 4-1, 4-2, . . . , 4-5, the single intervals 4-1, 4-2, . . . , 4-5 in this case having an interval width of 10° C. by way of example. The indicated temperature values 8 can relate to the mean values of the values provided by the interval boundaries, for example, or else to the value of the left-hand or the right-hand boundaries.

In the example shown, a total interval 5, which in this case comprises voltage values 7 from 3.3 V to 3.6 V by way of example, is furthermore divided into four single intervals 5-1, 5-2, . . . , 5-4, the single intervals 5-1, 5-2, . . . , 5-4 in this case having an interval width of 0.1 V by way of example. The indicated voltage values 7 can likewise relate to the mean values of the values provided by the interval boundaries, or else to the value of the left-hand or the right-hand boundary.

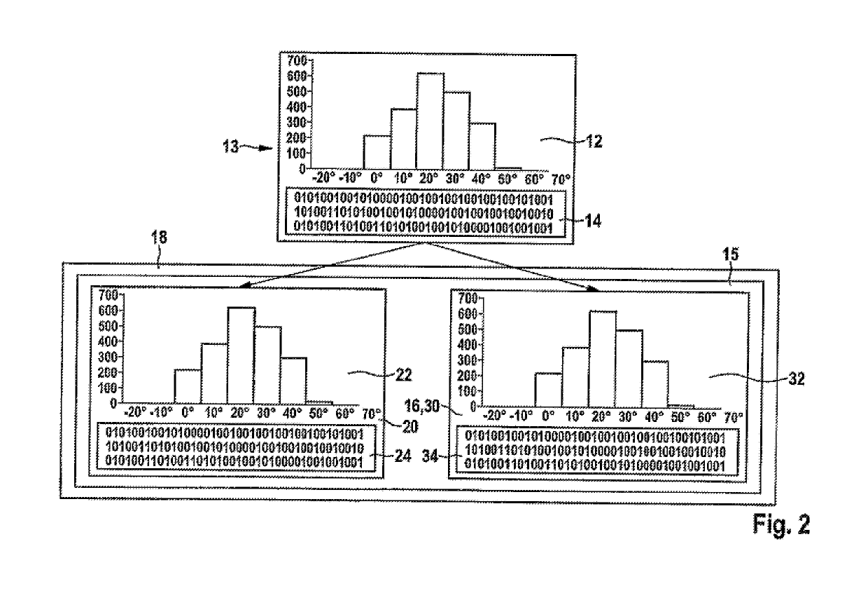

FIG. 2 shows a first data structure 13, which is created in the volatile memory, e.g. RAM, with a histogram 12 for a driving cycle. The histogram 12 is shown in one dimension in this case by way of example, but may naturally have arbitrary dimensions. In addition, the first data structure 13 comprises a checksum 14, which is ascertained by calculating a CRC (cyclic redundancy check) or by applying a hash function to the entries of the histogram 12, for example.

The first data structure 13 is copied and stored in duplicate in a second data structure 15 in a nonvolatile memory 18. The nonvolatile memory 18 may be associated with the battery management system, for example. A first version of the first data structure in the nonvolatile memory 18 can be designated as the original version 20 and a second version can be designated as a backup version 30. The second data structure 15 therefore comprises the original version 20 and the backup version 30. The histogram of the original version 20 is also designated the original histogram 22 and the checksum of the original version 20 is designated the original checksum 24. The backup version 30 accordingly comprises a backup histogram 32 and a backup checksum 34 and forms the additional information carrier 16, which is set up to reconstruct the histogram 12 that originally needs to be stored.

Before a driving cycle, the original version 20 with the original histogram 22 and the original checksum 24 is read from a nonvolatile memory 18. The consistency of the original histogram 22 is checked by means of the original checksum 24. If the original checksum 24 is correct, the original histogram 22 can be used for this driving cycle. If the original checksum 24 is not correct, the backup version 30 with the backup histogram 32 and the backup checksum 34 is read from the nonvolatile memory 18. The backup checksum 34 is used to check whether the backup histogram 32 is correct.

If the original checksum 24 is incorrect, a cause is ascertained and countermeasures are initiated in accordance with a few preferred embodiments of the method according to the disclosure. If the original histogram 22 is corrupt on account of memory errors, provision may be made for the memory cells in question to be marked as unusable and avoided. Although duplicate errors that relate both to the original histogram 22 and to the backup histogram 32 are identified by this method, they cannot be rectified. The extremely unlikely case that the original histogram 22 and the backup histogram 32 are erroneous at exactly the same location cannot be identified.

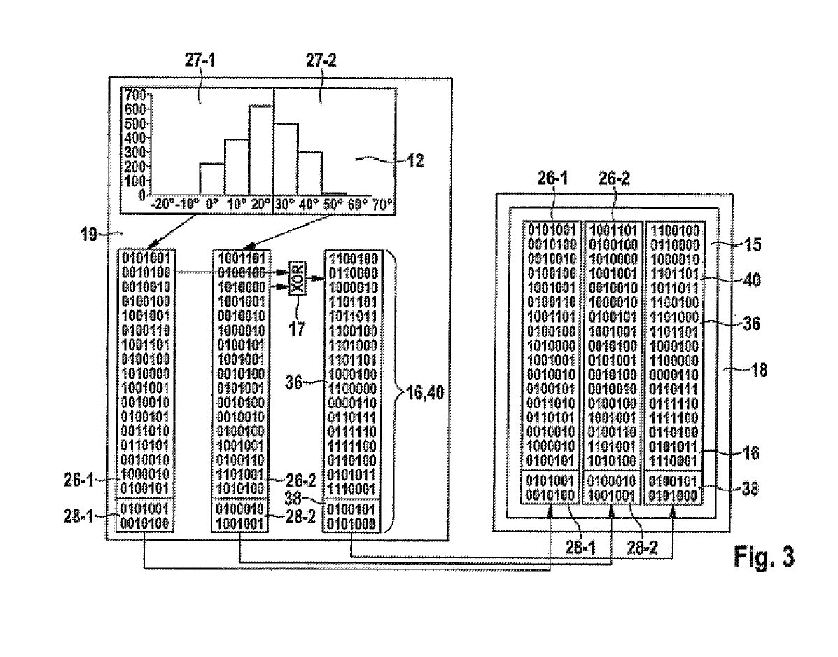

FIG. 3 shows a data structure 15 that is stored in a nonvolatile memory 18 and that comprises a histogram 12, broken down into partitions 26-1, 26-2, and an additional information carrier 16. For the sake of clarity, in FIG. 3 the same reference symbols are allocated for the elements in the volatile memory 19 and in the nonvolatile memory 18.

During a driving cycle, a histogram 12 is created by the battery controller in the volatile memory. The histogram is then split into a defined number of partitions 26 in the volatile memory. In FIG. 3, the histogram 12, which is one-dimensional by way of example, is split into two partitions 26-1, 26-2. Ideally, both partitions 26-1, 26-2 are chosen to be of the same magnitude in relation to the byte magnitude. By way of example, the partitioning can be effected by dividing value ranges of the captured use data. Reference symbols 27-1, 27-2 are used to graphically illustrate the partitions 26-1, 26-2 in the histogram 12 that are created by dividing value ranges. Partitions that are not of the same magnitude are also possible. By way of example, the histogram described with reference to FIG. 1 can be split into a first partition with entries for the temperature intervals 10°, 20° and 30° and into a second partition with entries for the temperature intervals 40° and 50°.

For each partition 26-1, 26-2, a checksum 28-1, 28-2 is calculated, as described with reference to FIG. 2. Furthermore, an additional information carrier 16 in the form of parity data 40 is formed. In the exemplary embodiment shown in FIG. 3, the partitions 26-1, 26-2 are processed in blocks of 7 bits by way of example, and for each 7 bits a 7-bit parity value is stored that is calculated as an XOR value over the individual 7 bits. An appropriate operator is shown in FIG. 3 by means of reference symbol 17. Alternatively, it is also possible for byte-by-byte processing to take place and for a parity byte to be ascertained. Alternative rhythms with more or fewer than 7 or 8 bits can likewise be performed, particularly taking account of the data coding used for the partitions 26-1, 26-2. For the checksums 28, it is similarly likewise possible to create a piece of parity information 38. The nonvolatile memory 18 is used to store the two partitions 26-1, 26-2 with the checksums 28-1, 28-2 together with the parity information 36 and the parity information for the checksums 38.

Before each driving cycle, the histogram, i.e. in the example shown the partitions 26-1, 26-2 with parity information 36, the checksums 28 and the parity information 38 for the checksums, is read from the nonvolatile memory 18. The checksums 28-1, 28-2 are used to check whether the partitions 26-1, 26-2 have been read correctly. If all the checksums 28-1, 28-2 are correct, the histogram can be used for this driving cycle. If one of the checksums 28-1, 28-2 is not correct, it is possible for the histogram to be reconstructed. If the checksum of one of the partitions 26-1, 26-2 is not correct, the relevant partition is reconstructed using the remaining partitions and the parity information 36. This involves the execution of an XOR function using the values of the remaining partitions, in the example shown just one further partition. A comparison with the parity information allows the corrupt partition to be reconstructed, as illustrated briefly below with the aid of an example.

Example of a Reconstruction:

Partition 1: 0011011001

Partition 2: 0110100110

Parity: 0101111111

During reading, it is found that partition 1 is faulty, for example. The reconstruction of this partition is obtained from partition 2 by means of the XOR parity:

Partition 2: 0110100110

XOR: 0101111111

Partition 1: 0011011001

The method presented allows single errors to be identified and rectified. Duplicate errors, i.e. when multiple partitions are identified as corrupt at the same time, cannot be rectified.

In comparison with the variant in which the entire histogram is stored with a backup version, the described variant of the storage of the parity information has the advantage that the memory requirement is lower. In the case of duplicate storage, twice the memory requirement is obtained in comparison with single storage. In the case of the latter alternative, the histogram is partitioned and additionally the parity information in the magnitude of the largest partition is stored. The additional requirement is accordingly dependent on the number of partitions. If two partitions are existent, the memory requirement is 1.5 times as great as the original histogram, namely 2 partitions and the parity information in a magnitude of one partition, i.e. in half the magnitude of the histogram. If the number of partitions is 3, a memory requirement with a factor of 1.33 is obtained, i.e. 3 partitions plus the parity information in a magnitude of one partition, i.e. one third of the histogram. Although the use of multiple partitions reduces the additional involvement for the parity information, there is an increase in the required memory space for managing the additional partitions.

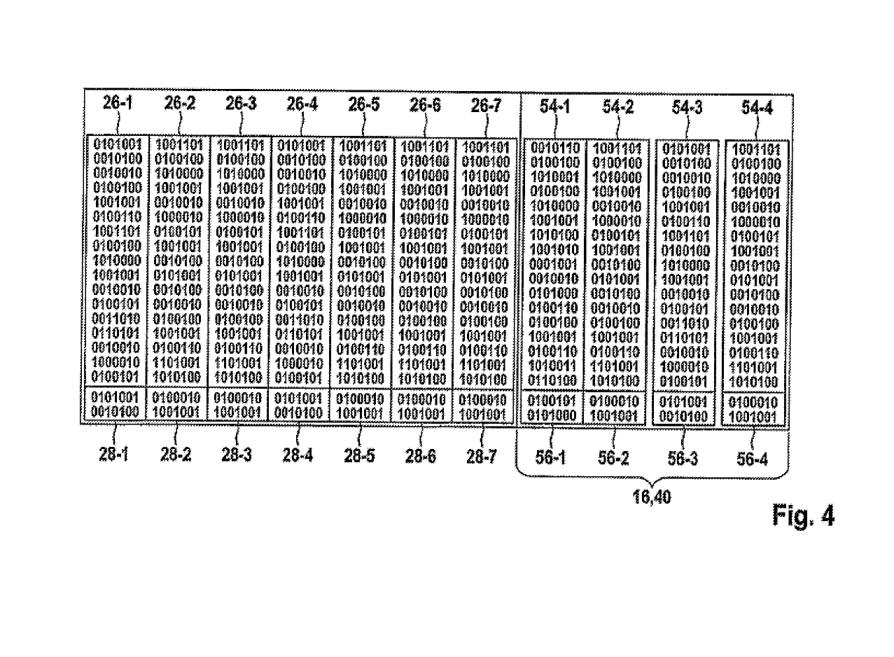

FIG. 4 shows a further alternative for reconstruction data that can be derived from known RAID systems. A histogram—not shown—is broken down into seven partitions 26-1, 26-2, . . . , 26-7. For each partition, an appropriate checksum 28-1, 28-2, . . . , 28-7 is calculated and stored as well, as described with reference to FIG. 2, for example. As an additional information carrier 16, parity information 54-1, 54-2, 54-3, 54-4 and associated checksums 56-1, 56-2, 56-3, 56-4 are ascertained and stored by a combination of various methods, for example RAID4 and RAID5. The parity information 54-1, 54-2, 54-3, 54-4 is set up such that multiple errors in the partitions can be corrected. In comparison with the exemplary embodiment described with reference to FIG. 3, more memory space is taken up by the reconstruction data, however.

The checksums 28 are used to identify whether one or more partitions 26 are corrupt. The reconstruction data are used to restore the corrupt partitions. Preferably, this is followed by diagnosis to determine why the partition is corrupt. The reason for this could be a faulty memory cell in a nonvolatile memory for example. The controller is provided with the option of identifying the memory faults and takes into account that faulty memory cells no longer continue to be used.

The disclosure is not limited to the exemplary embodiments described here and the aspects highlighted therein. On the contrary, a large number of modifications that are within the scope of action of a person skilled in the art are possible within the scope indicated by the disclosure.

What is claimed is:

1. A method for providing information for maintenance and service purposes for a battery unit comprising:
capturing and quantizing use data for a battery unit;
generating a histogram that has frequency values for the occurrence of particular values of the individual quantized use data items or values derived therefrom;
ascertaining at least one additional information carrier that is set up to reconstruct the histogram; and
storing the histogram and the at least one additional information carrier in a nonvolatile memory.

2. The method according to claim 1, wherein the at least one additional information carrier includes a copy of the histogram.

3. The method according to claim 1, further comprising:
generating at least one checksum configured to enable identification of erroneous information.

4. The method according to claim 1, wherein the histogram is split into partitions.

5. The method according to claim 4, wherein the at least one additional information carrier comprises parity data for the partitions.

6. A data structure comprising:
at least one histogram including frequency values for the occurrence of particular values of quantized use data or values derived therefrom; and
at least one additional information carrier that is set up to reconstruct the histogram when the data structure is read by a computer device,
wherein the data structure has been created during the performance the method according to claim 1.

7. A programmable computer device comprising:
a memory; and
a processor configured to execute a computer program stored in the memory to implement the method according to claim 1.

8. A battery management system comprising:
a capturing unit configured to capture use data for a battery unit;
a quantizing unit configured to quantize the captured use data;
a histogram unit configured to produce a histogram that has frequency values for the occurrence of particular values of the individual quantized use data items or values derived therefrom;
a carrier unit configured to ascertain an additional information carrier that is set up to reconstruct the histogram; and
and a storing unit configured to store the histogram and the additional information carrier in a nonvolatile memory.

9. A battery comprising:
a plurality of battery cells; and
a battery management system including (i) a capturing unit configured to capture use data for the battery, (ii) a quantizing unit configured to quantize the captured use data, (iii) a histogram unit configured to produce a histogram that has frequency values for the occurrence of particular values of the individual quantized use data items or values derived therefrom, (iv) a carrier unit configured to ascertain an additional information carrier that is set up to reconstruct the histogram, and (v) a storing unit configured to store the histogram and the additional information carrier in a nonvolatile memory,
wherein the battery is configured to be connected to a drive system in a motor vehicle.

10. A motor vehicle comprising:
the drive system for the motor vehicle; and
the battery according to claim 9, wherein the battery is connected to the drive system in the motor vehicle.
